(19) United States
(12) Patent Application Publication
(10) Pub. No.: US 2026/0109116 A1
(43) Pub. Date: Apr. 23, 2026

(54) MANUFACTURING APPARATUS FOR DISPLAY DEVICE, METHOD OF MANUFACTURING DISPLAY DEVICE USING SAME, AND ELECTRONIC DEVICE INCLUDING DISPLAY DEVICE

(71) Applicant: Samsung Display Co., Ltd., Yongin-si (KR)

(72) Inventors: Hong Chul SHIN, Yongin-si (KR); Tetsuya OKAMOTO, Yongin-si (KR); Min Seok KANG, Yongin-si (KR)

(21) Appl. No.: 19/317,286

(22) Filed: Sep. 3, 2025

(30) Foreign Application Priority Data
Oct. 22, 2024 (KR) 10-2024-0145219

(51) Int. Cl. B29C 65/70; B29C 65/00; B29C 65/48; B29L 31/34; G09G 3/20

(52) U.S. Cl. CPC B29C 65/70; B29C 65/48; B29C 66/7315; B29C 66/8242; G09G 3/2092; B29L 2031/3475; G09G 2330/02

(57) ABSTRACT

A manufacturing apparatus for a display device includes: a pad assembly including a body, a core member, and a pad coupled together and configured to move in a vertical direction; and a jig configured to accommodate at least a portion of the pad assembly. At least a portion of the core member is in a body accommodating area formed by the body, and the core member has an expansion opening covered by the pad and facing an inner surface of the pad.

### CROSS-REFERENCE TO RELATED APPLICATION

The present application claims priority to and benefit of Korean Patent Application No. 10-2024-0145219, filed on Oct. 22, 2024, in the Korean Intellectual Property Office, the entire disclosure of which is incorporated herein by reference.

### BACKGROUND

### 1. Field

Aspects of embodiments of the present disclosure relate to a manufacturing apparatus for a display device, a method of manufacturing a display device using a same, and an electronic device including the display device.

### 2. Description of the Related Art

Recently, as interest in information display is increasing, research and development of display devices are being continuously conducted. In addition, as an application field of the display device is further expanded, interest in a flexible display device is also increasing.

A display device may include a display panel and a window disposed on the display panel to protect the display panel. For the display device to have a flexible characteristic, the display panel and the window must be suitably molded.

### SUMMARY

Embodiments of the present disclosure provide a manufacturing apparatus for a display device in which a display panel and a cover window may be closely attached to each other, a method of manufacturing the display device using a same, and an electronic device including the display device.

Embodiments of the present disclosure also provide a manufacturing apparatus for a display device in which a molding process for a display panel and a cover window may be suitably performed, a method of manufacturing a display device using a same, and an electronic device including the display device.

According to an embodiment of the present disclosure, a manufacturing apparatus for a display device includes: a pad assembly including a body, a core member, and a pad coupled together and configured to move in a vertical direction and a jig configured to accommodate at least a portion of the pad assembly. At least a portion of the core member is in a body accommodating area formed by the body, and the core member has an expansion opening covered by the pad and facing an inner surface of the pad.

According to an embodiment, the display device may include a display panel. The pad assembly may form an area at where the display panel is arranged. At least a portion of the pad may be in the body accommodating area, and at least another portion of the pad may extend around an outer surface of at least a portion of the core member that is not in the body accommodating area.

According to an embodiment, the body, the core member, and the pad may be assembled together to form the pad assembly.

According to an embodiment, the manufacturing apparatus may further include a capping layer between the body and the pad in the body accommodating area. The body, the core member, and the pad may be detachably bonded to each other.

According to an embodiment, the core member may have a core accommodating area, and at least a portion of the pad may protrude and may in close contact an inner surface of the core member in the core accommodating area.

According to an embodiment, the core member may have a core base portion and a core edge portion which are integral with each other. The core base portion may be in the body accommodating area, the core edge portion may not be in the body accommodating area. The core base portion may have a shape and a size corresponding to the body accommodating area.

According to an embodiment, the core edge portion may be covered by a portion of the pad, and the expansion opening may be formed in at least a portion of the core edge portion.

According to an embodiment, the core member may have an air injection opening and an air path fluidly connecting the air injection opening and the expansion opening.

According to an embodiment, the air path may have portions extending in a plurality of different directions.

According to an embodiment, the expansion opening may include a plurality of expansion openings. A first group of the plurality of expansion openings may be disposed at vertex areas of the core edge portion.

According to an embodiment, the plurality of expansion openings may include a first expansion opening, a second expansion opening, and a third expansion opening facing in different directions and at different ones of the vertex areas. The first expansion opening, the second expansion opening, and the third expansion opening may be fluidly connected to the same air injection opening.

According to an embodiment, a second group of the plurality of expansion openings may be formed at sides of the core edge portion.

According to an embodiment, the pad may include a pad base portion and a pad edge portion integrally formed with each other. The pad base portion may be between the body and the core member in the body accommodating area. The pad edge portion may not be in the body accommodating area and may not be covered by the body.

According to an embodiment, air supplied through the expansion opening may push the inner surface of the pad, and an outer surface shape of the pad may be changed by the air pushing the inner surface of the pad.

According to an embodiment, the manufacturing apparatus may further include a moving member configured to move the pad assembly. The jig may include a first jig and a second jig facing the first jig, and the second jig may have an inner surface having a curved shape to receive a cover window.

According to an embodiment of the present disclosure, a method of manufacturing a display device includes: providing a pad assembly including a body, a core member, and a pad coupled together, a display panel on the pad assembly, and a cover window facing the display panel; adjusting a shape of the pad; and molding the display panel and the cover window after the adjusting the shape of the pad.

According to an embodiment, the adjusting the shape of the pad may include expanding a portion of the pad that is not covered by the body by allowing air provided through an air path formed in the core member to push an inner surface of the pad.

According to an embodiment, in the adjusting the shape of the pad, a portion of the pad in a body accommodating area formed by the body may not be expanded.

According to an embodiment, the adjusting the shape of the pad may include determining whether or not the pad is expanded to within a range based on an internal pressure of the pad and an external shape of the pad.

According to an embodiment, the molding may include arranging the pad assembly in a first jig and supporting the cover window in a second jig that is adjacent to the first jig and molding the display panel to correspond to a shape of the pad.

According to an embodiment of the present disclosure, an electronic device includes: a processor configured to provide input image data; a display device configured to display an image based on the input image data, including sub-pixel areas, and manufactured by the method; and a power supply configured to supply power to the display device.

According to an embodiment of the present disclosure, a manufacturing apparatus for a display device in which a display panel and a cover window may be closely attached to each other, a method of manufacturing the display device by using a same, and an electronic device including the display device may be provided.

According to an embodiment of the present disclosure, a manufacturing apparatus for a display device in which a molding process for a display panel and a cover window may be suitably performed, a method of manufacturing a display device using a same, and an electronic device including the display device may be provided.

### BRIEF DESCRIPTION OF THE DRAWINGS

The above and other aspects and features of the present disclosure will become more apparent by describing, in detail, embodiments thereof with reference to the accompanying drawings, in which:

FIG. 1 is a schematic perspective view illustrating a display device according to an embodiment;

FIG. 2 is a schematic cross-sectional view illustrating a display device according to an embodiment;

FIG. 3 is a schematic perspective view illustrating a pad assembly included in a manufacturing apparatus for a display device according to an embodiment;

FIGS. 4 to 6 are schematic cross-sectional views illustrating a pad assembly according to various embodiments;

FIG. 7 is a schematic enlarged view of the region EA1 in FIG. 4;

FIG. 8 is a schematic perspective view illustrating a core member according to an embodiment;

FIGS. 9 and 10 are schematic plan views illustrating a core member according to an embodiment;

FIG. 11 is a flowchart describing steps of a method of manufacturing a display device according to an embodiment;

FIGS. 12 to 14 are schematic drawings illustrating steps of a method of manufacturing a display device according to an embodiment;

FIG. 15 is a schematic block diagram illustrating an electronic device including a display device according to an embodiment;

FIG. 16 is a schematic diagram illustrating an example in which the electronic device shown in FIG. 15 is implemented as a smartphone; and

FIG. 17 is a schematic diagram illustrating an example in which the electronic device shown in FIG. 15 is implemented as a tablet PC.

### DETAILED DESCRIPTION

The present disclosure may be modified in various manners and may have various forms. Therefore, while embodiments will be illustrated in the drawings and will be described, in detail, in the specification, it should be understood that the present disclosure is not intended to be limited to the disclosed forms. Rather, the present disclosure includes all modifications, equivalents, and substitutions within the spirit and technical scope of the present disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S. C. § 112(a) and 35 U.S. C. § 132(a).

The present disclosure relates to a manufacturing apparatus for a display device, a method of manufacturing a display device using a same, and an electronic device including a display device. Hereinafter, a manufacturing apparatus for a display device, a method of manufacturing a display device using a same, and an electronic device including a display device according to an embodiment are described with reference to the accompanying drawings.

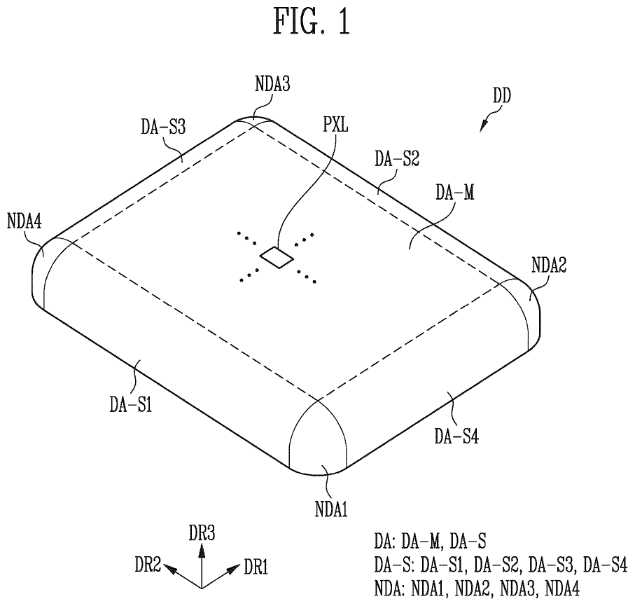

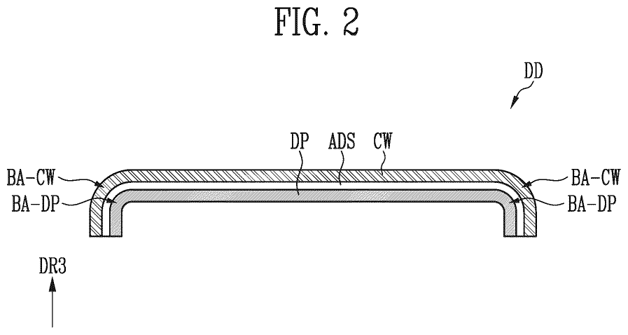

With reference to FIGS. 1 and 2, a display device DD according to an embodiment is described.

FIG. 1 is a schematic perspective view illustrating a display device according to an embodiment. FIG. 2 is a schematic cross-sectional view illustrating a display device according to an embodiment.

Referring to FIGS. 1 and 2, the display device DD may include a display panel DP, an adhesive layer ADS, and a cover window CW.

The display device DD may include pixels PXL. The pixels PXL may provide (e.g., may emit) light and may include one or more sub-pixels.

The display device DD may have a display area DA at where pixels PXL are formed and a non-display area NDA at where the pixels PXL are not formed.

The display area DA may be formed in various areas of (e.g., may have various sizes and shapes on) the display device DD. For example, the display area DA may have a main display area DA-M and a side display area DA-S.

The main display area DA-M may be a flat area. For example, the main display area DA-M may have a generally flat surface. The main display area DA-M may be generally parallel to a plane at where a base layer (e.g., a substrate) forming the display device DD is disposed.

The plane, as defined in this specification, may be defined based on the plane at where the base layer (e.g., the substrate) forming the display device DD is disposed and as a direction extending in a first direction DR1 and a second direction DR2 crossing (e.g., intersecting) the first direction DR1. According to an embodiment, a third direction DR3 may be a thickness direction of the base layer (e.g., the substrate) forming the display device DD, and the third direction DR3 may be a light emission direction of the display device DD.

The side display area DA-S may be at a peripheral portion of the main display area DA-M. The side display area DA-S may be formed in an area at where at least a portion of the display device DD is bent or curved. For example, the display device DD may be bent on first to fourth sides, and the side display area DA-S may include a first side display area DA-S1 formed on the first side, a second side display area DA-S2 formed on the second side, a third side display area DA-S3 formed on the third side, and a fourth side display area DA-S4 formed on the fourth side. According to an embodiment, the side display area DA-S may be a bezel area at where light may be provided (e.g., from which light may be emitted).

The non-display area NDA may be at a periphery portion of the display area DA. The non-display area NDA may be an area at where light is not recognized (e.g., at where light is not emitted).

According to an embodiment, the non-display area NDA may be formed in at least a portion of an area where the display device DD is bent. For example, the non-display area NDA may be disposed between adjacent side display areas DA-S. The non-display area NDA may be formed at each of vertices (or corners) of the display device DD. For example, the non-display area NDA may include a first non-display area NDA1 adjacent to a first vertex of the main display area DA-M, a second non-display area NDA2 adjacent to a second vertex of the main display area DA-M, a third non-display area NDA3 adjacent to a third vertex of the main display area DA-M, and a fourth non-display area NDA4 adjacent to a fourth vertex of the main display area DA-M. However, a range in which the non-display area NDA is formed is not limited to a specific example.

The display panel DP may be configured to emit light. The display panel DP may include various light sources. For example, the display panel DP may be an organic light emitting panel including an organic light emitting element or may be an inorganic light emitting panel including an inorganic light emitting element (e.g., a micro light emitting diode (LED)). However, the present disclosure is not limited to a specific example.

The display panel DP may have a flexible characteristic. For example, at least a portion of the display panel DP may be bent. According to an embodiment, the display panel DP may include a relatively flexible substrate. The substrate may include polyimide or the like, but the present disclosure is not limited thereto.

The display panel DP may have a panel bending area BA-DP. For example, the display panel DP may be bent in the panel bending area BA-DP and may have a curved cross-sectional shape. According to an embodiment, the panel bending area BA-DP may be formed on one or more sides of the display panel DP. For example, the panel bending area BA-DP may be formed on each of upper, lower, left, and right sides of the display panel DP.

According to an embodiment, the display panel DP may have a shape which is bent downwardly. For example, a convex cross-section may be formed on a front surface of the display panel DP (e.g., a surface of the display panel DP facing the cover window CW), and a concave cross-section may be formed on a back surface of the display panel DP (e.g., another surface of the display panel DP which does not face the cover window CW).

The adhesive layer ADS may couple the display panel DP and the cover window CW with each other. The adhesive layer ADS may be interposed between the display panel DP and the cover window CW and may have a cross-sectional shape corresponding to an upper surface of the display panel DP and a lower surface of the cover window CW.

The adhesive layer ADS may include various light transmitting adhesive materials. For example, the adhesive layer ADS may include an optically clear adhesive film (OCA), an optically clear resin (OCR), or a pressure sensitive adhesive film (PSA). However, the present disclosure is not limited thereto.

The cover window CW may be disposed on the adhesive layer ADS. The cover window CW may include various materials configured to transmit light and suitable for protecting the display panel DP disposed under the cover window CW.

The cover window CW may have a window bending area BA-CW. For example, the cover window CW may be bent in the window bending area BA-CW and may have a curved cross-sectional shape.

The cover window CW may have a shape bent downwardly. For example, a convex cross-section may be formed on a front surface of the cover window CW, and a concave cross-section may be formed on a back surface of the cover window CW.

The panel bending area BA-DP and the window bending area BA-CW may include (e.g., may overlap) the side display area DA-S and the non-display area NDA shown in FIG. 1. For example, at least a portion of the display device DD may be bent, and the display device DD may provide light or may not provide light in a bent area.

According to an embodiment, because the display device DD has a bent shape, the display device DD may be applied to various electronic devices, and a display device DD with an improved user aesthetic and convenience may be provided.

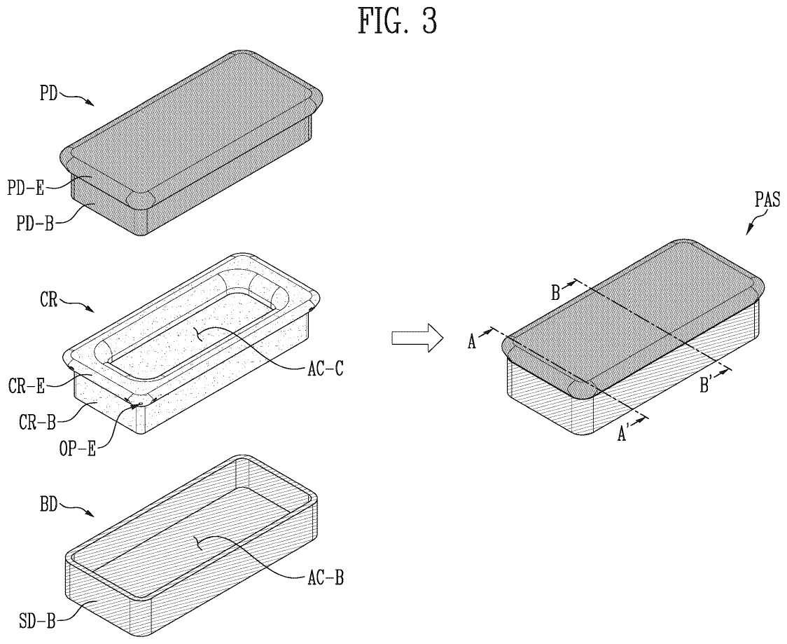

With reference to FIGS. 3 to 10, a manufacturing apparatus for a display device DD according to an embodiment is described. For convenience of description, content that may overlap or is substantially similar to the content described above is briefly described or is omitted.

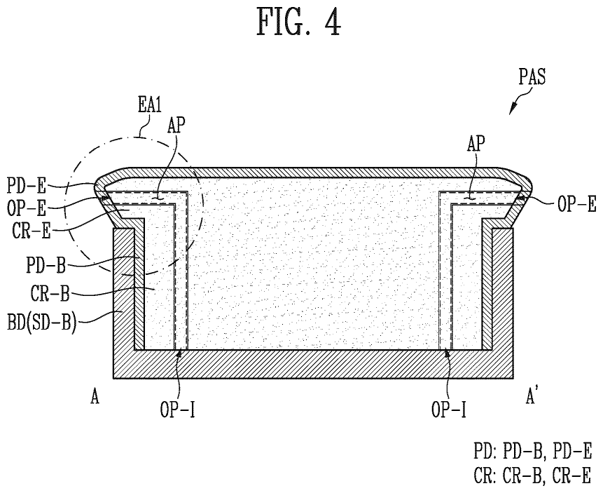

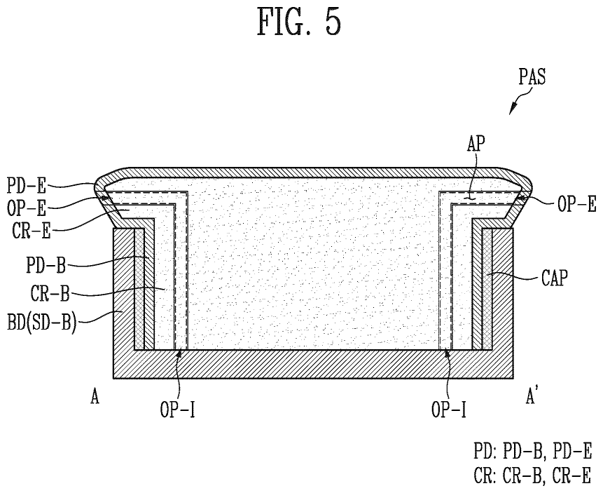

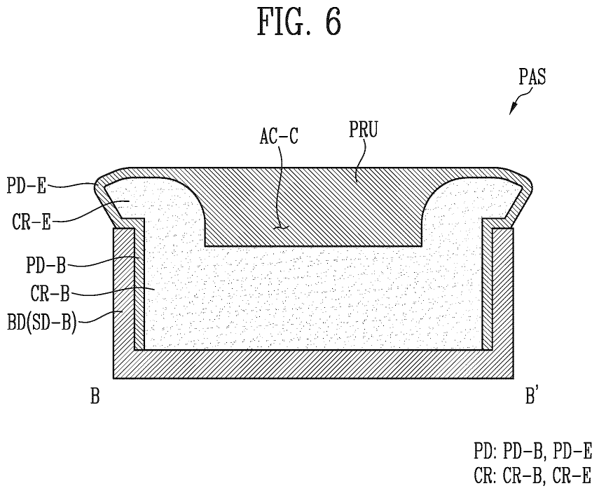

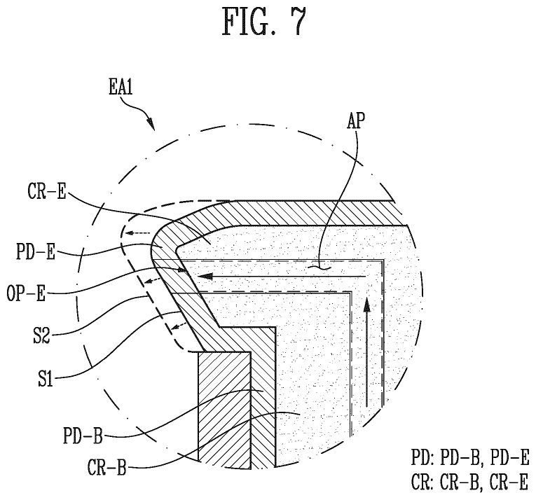

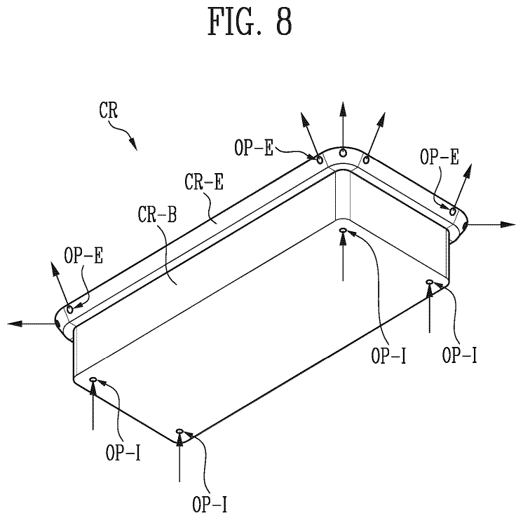

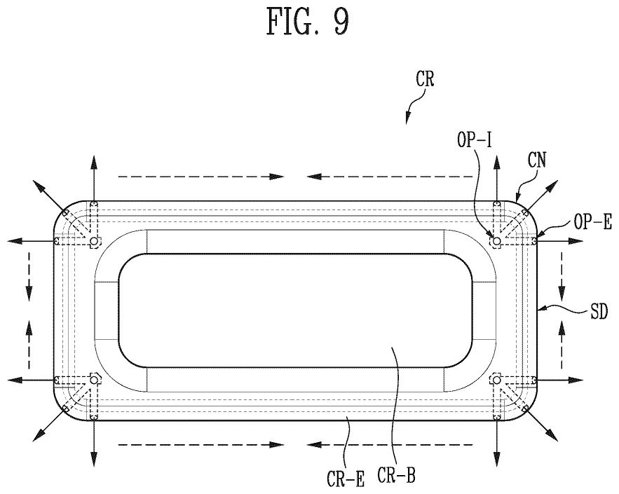

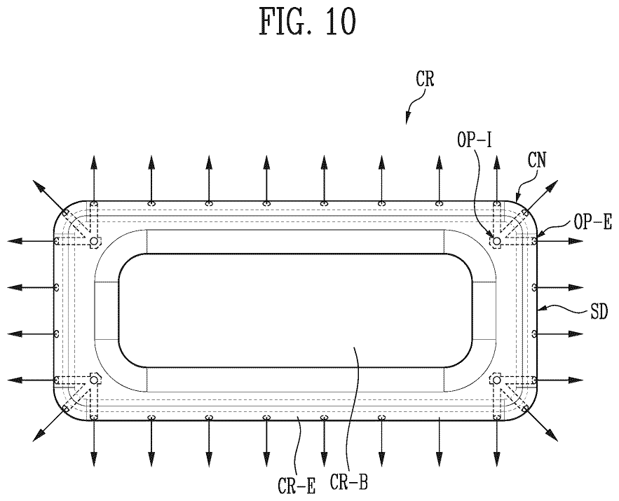

FIG. 3 is a schematic perspective view illustrating a pad assembly included in a manufacturing apparatus for a display device according to an embodiment. FIGS. 4 to 6 are schematic cross-sectional views illustrating a pad assembly according to an embodiment. FIGS. 4 and 5 are schematic cross-sectional views taken along the line A-A′ in FIG. 3. FIG. 6 is a schematic cross-sectional view taken along the line B-B′ in FIG. 3. Accordingly, FIGS. 4 to 6 show a core base portion CR-B of a core member CR, a core edge portion CR-E, and portions of a pad assembly PAS adjacent to the core base portion CR-B and the core edge portion CR-E. FIG. 7 is a schematic enlarged view of the area EA1 in FIG. 4. FIG. 8 is a schematic perspective view illustrating a core member according to an embodiment. FIGS. 9 and 10 are schematic plan views illustrating a core member according to an embodiment.

The display device DD may include process facilities for molding the display panel DP and the cover window CW. For example, a manufacturing apparatus for a display device DD according to an embodiment may include the pad assembly PAS.

The pad assembly PAS may provide an area where the display panel DP is settled (or disposed or arranged) during a molding process for the display panel DP. For example, the display panel DP may be molded to correspond to a shape of an upper surface of the pad assembly PAS.

The pad assembly PAS may include a body BD, a core member CR, and a pad PD.

According to an embodiment, the body BD, the core member CR, and the pad PD may form a set. For example, the body BD, the core member CR, and the pad PD may be coupled with each other. The body BD, the core member CR, and the pad PD may form a pad assembly PAS.

According to an embodiment, the core member CR may be provided (e.g., disposed or arranged) in a body accommodating area AC-B formed by the body BD.

According to an embodiment, at least a portion of a pad PD may be provided (e.g., disposed or arranged) in a core accommodating area AC-C formed by the core member CR (refer to, for example, FIG. 6). Accordingly, the pad PD may be stably coupled with the core member CR. For example, the pad PD may have a protrusion portion PRU protruding downwardly from a central area, and the protrusion portion PRU of the pad PD may be provided (e.g., disposed or received) in the core accommodating area AC-C. The protrusion portion PRU of the pad PD may be in close contact with (e.g., may contact) an inner surface of the core member CR forming the core accommodating area AC-C. In such an embodiment, even when a shape of the pad PD is expanded through an air injection process, a combining state between the pad PD and the core member CR may be stably maintained. For example, even though a pad edge portion PD-E is expanded, at least a portion of the pad PD in the core accommodating area AC-C may still be disposed, and a risk that the combining state between the pad PD and the core member CR is released may be reduced.

According to an embodiment, the core accommodating area AC-C may be an area surrounded by at least a portion of the core member CR. For example, the core accommodating area AC-C may be surrounded by the core base portion CR-B and the core edge portion CR-E, and each of the core base portion CR-B and the core edge portion CR-E may include an inner surface facing the core accommodating area AC-C.

At least another portion of the pad PD may surround (e.g., may extend around) an outer surface of the core member CR, and thus, the pad PD may be in close contact with the outer surface of the core member CR.

According to an embodiment, the body BD, the core member CR, and the pad PD may be assembled to each other to form the pad assembly PAS. In such an embodiment, the body BD, the core member CR, and the pad PD may be closely coupled (e.g., bonded) with each other. However, the present disclosure is not limited thereto. According to another embodiment, the body BD, the core member CR, and the pad PD may be detachably bonded (e.g., detachably coupled) with each other such that they remain separable from each other to form the pad assembly PAS.

The body BD may form a lower portion of the pad assembly PAS. The body BD may include a relatively hard material. Accordingly, the body BD may stably support a lower portion of the core member CR and the pad PD.

The body BD may include (or may form) a body accommodating area AC-B. For example, the body BD may include body side portions SD-B forming the body accommodating area AC-B. The body side portions SD-B may surround (e.g., may extend around) an area and may form the body accommodating area AC_B opened in a direction.

The core member CR may form a central portion of the pad assembly PAS. At least a portion of the core member CR may be provided in the body accommodating area AC-B, and at least another portion of the core member CR may not be provided in the body accommodating area AC-B.

The core member CR may include the core base portion CR-B and the core edge portion CR-E. The core base portion CR-B and the core edge portion CR-E may be integral and may be integrally formed.

The core base portion CR-B may form a lower portion of the core member CR. The core base portion CR-B may be disposed in the body accommodating area AC-B when the core member CR and the body BD are coupled with each other.

The core base portion CR-B may have a shape and a size corresponding to the body accommodating area AC-B so that the core member CR may be closely coupled with the body BD in case that a portion of the pad PD is interposed between the core member CR and the body side portion SD-B.

For example (refer to, for example, FIG. 4), a surface of the pad PD may be adjacent to (e.g., may be directly adjacent to) the core base portion CR-B, and another surface of the pad PD may be adjacent to (e.g., may be directly adjacent to) the body side portion SD-B when the pad assembly PAS is formed.

In another embodiment (refer to, for example, FIG. 5), the pad assembly PAS may further include a capping layer CAP disposed between the core member CR (or the pad PD) and the body BD (e.g., the body side portion SD-B). In such an embodiment, a surface of the pad PD may be adjacent to (e.g., may be directly adjacent to) the core base portion CR-B in the body accommodating area AC-B, another surface of the pad PD may be adjacent to (e.g., directly adjacent to) a surface of the capping layer CAP, and another surface of the capping layer CAP may be adjacent to (e.g., directly adjacent to) the body side portion SD-B when the pad assembly PAS is formed.

According to an embodiment, the body BD, the core member CR, and the pad PD may be coupled to be interchangeable with each other to form the pad assembly PAS when the pad assembly PAS further includes the capping layer CAP as shown in FIG. 5. For example, for the body BD, the core member CR, and the pad PD to be provided so as to be interchangeable, the body BD, the core member CR, and the pad PD should not be in excessively close contact with each other. However, for the pad assembly PAS to have a robust structure, the body BD, the core member CR, and the pad PD should be stably coupled. According to an embodiment, the capping layer CAP may be interposed between the pad PD and the body BD in case that the pad assembly PAS is formed, and thus, the body BD, the core member CR, and the pad PD may be coupled to be interchangeable with each other and may be in close contact with each other.

The core edge portion CR-E may form an upper portion of the core member CR. The core edge portion CR-E may not be covered by the body BD (e.g., the body side portion SD-B) when the core member CR is coupled with the body BD.

The core edge portion CR-E may not be provided inside (e.g., may be outside of) the body accommodating area AC-B and may be exposed to an outside of the body accommodating area AC-B. For example, the core edge portion CR-E may protrude in a direction.

According to an embodiment, the core member CR may include an expansion opening OP-E. The expansion opening OP-E may be formed in at least a portion of the core edge portion CR-E. The expansion opening OP-E may be directly adjacent to an inner surface of the pad PD (e.g., the pad edge portion PD-E). The expansion opening OP-E may be covered by the pad PD (e.g., the pad edge portion PD-E). The expansion opening OP-E may face the inner surface of the pad PD (e.g., the pad edge portion PD-E).

The expansion opening OP-E may be fluidly connected to (e.g., may be in fluid communication with) an air path AP and an air injection opening OP-I.

The expansion opening OP-E may include a plurality of expansion openings OP-E. The number of the plurality of expansion openings OP-E is not limited. The expansion openings OP-E may be formed in vertex areas CN of the core edge portion CR-E and areas adjacent to the vertex areas CN.

According to an embodiment, the core member CR may include the air injection opening OP-I. The air injection opening OP-I may be formed in at least a portion of the core base portion CR-B. The air injection opening OP-I may be formed in a lower portion of the core member CR.

The air injection opening OP-I may be fluidly connected to an external air injection member (e.g., a pump or the like) and may receive air.

According to an embodiment, the core member CR may include the air path AP. The air path AP may fluidly connect between the air injection opening OP-I and the expansion opening OP-E. Accordingly, air supplied through the air injection opening OP-I may be provided to the expansion opening OP-E through the air path AP.

The air path AP may include portions extending in two or more directions. For example, a portion of the air path AP may extend in a direction from a lower portion of the pad assembly PAS to an upper portion (e.g., a direction in which the body side portion SD-B extends). Another portion of the air path AP may extend in a direction from a center of the pad assembly PAS to an edge (e.g., a direction in which a lower portion of the body BD extends). Accordingly, air provided from the lower portion of the pad assembly PAS may be provided to the expansion opening OP-E adjacent to the pad edge portion PD-E formed at a relatively upper edge.

The pad PD may form an upper portion of the pad assembly PAS. A portion of the pad PD may be disposed in the core accommodating area AC-C, at least another portion of the pad PD may be disposed on the core edge portion CR-E, and at least yet another portion of the pad PD may be disposed on the core base portion CR-B and disposed in the body accommodating area AC-B. According to an embodiment, the pad PD may include a material of silicon or the like, but the present disclosure is not limited thereto.

The pad PD may include a pad base portion PD-B and the pad edge portion PD-E. The pad base portion PD-B and the pad edge portion PD-E may be integral and may be integrally formed.

The pad base portion PD-B may form a lower portion of the pad PD. The pad base portion PD-B may cover an outer surface of the core base portion CR-B and may be disposed in the body accommodating area AC-B when the pad assembly PAS is formed. The pad base portion PD-B may be disposed between the body side portion SD and the core base portion CR-B in the body accommodating area AC-B.

The pad base portion PD-B may have a shape corresponding to an outer surface of the core base portion CR-B. Accordingly, the pad base portion PD-B may be in close contact with the core base portion CR-B.

The pad base portion PD-B may be adjacent to (e.g., directly adjacent to) an inner surface of the body BD (e.g., a body side portion BD-S). Accordingly, an area at where the pad base portion PD-B is disposed may be limited by the body BD.

The pad edge PD-E may form an upper portion of the pad PD. The pad edge part PD-E may form an uppermost portion when the pad assembly PAS is formed. The pad edge part PD-E may not be covered by the body BD, the core member CR, or the like.

The pad edge portion PD-E may form a base on which the display panel DP is disposed when a molding process for the display panel DP is performed. At least a portion of the pad edge portion PD-E may be bent. Accordingly, during a manufacturing process of the display device DD, the display panel DP may be molded to correspond to a shape of the panel edge portion PD-E.

The pad edge portion PD-E may cover an outer surface of the core edge portion CR-E. The pad edge portion PD-E may be in close contact with the core edge portion CR-E when the pad assembly PAS is formed.

The pad edge portion PD-E may not be covered by the body BD (e.g., the body side portion BD-S), and at least a portion of the pad edge portion PD-E may be adjacent to (e.g., directly adjacent to) an upper edge of the body BD (e.g., the body side portion BD-S). At least a portion of the pad edge portion PD-E may form an outermost portion of the pad assembly PAS and may be exposed. Accordingly, an area at where the pad edge portion PD-E may be disposed may not be limited by the body BD.

According to an embodiment, at least a portion of the pad PD may not be covered by the body BD. Accordingly, a shape of at least a portion of the pad PD may be changed when air is provided through the expansion opening OP-E to the inner surface of the pad PD. This is described in more detail later with reference to FIGS. 7 to 10.

Referring to FIGS. 7 to 10, the shape of the pad PD may be changed, and thus, an outer surface of the pad PD may be expanded.

For convenience of description, in FIGS. 7 to 10, flow of the air (e.g., the air flow) supplied through the air injection opening OP-I is illustrated by the arrow. For example, in FIG. 7, the flow of the air in the air path AP is indicated by solid arrows. In FIGS. 8 to 10, the flow of the air discharged through the expansion opening OP-E is indicated by solid arrows. In FIG. 9, the flow of the air which expands to a periphery after being discharged through the expansion opening OP-E is indicated by dotted arrows.

According to an embodiment, the air supplied through the air injection opening OP-I may move along the air path AP and may push the inner surface of the pad PD (e.g., the pad edge portion PD-E) through the expansion opening OP-E. As the inner surface of the pad edge portion PD-E is pushed, the outer surface of the pad PD may be expanded.

According to an embodiment, the expansion opening OP-E may have a plurality of expansion openings OP-E disposed in a vertex area CN of the core member CR. For example, the expansion opening OP-E may include first to third expansion openings facing three different directions in a vertex area CN of the core member CR. The first to third expansion openings may be fluidly connected to an air injection opening OP-I. Because the first to third expansion openings may provide air in different directions in a relatively adjacent area, the outer surface of the pad PD may be more clearly expanded in the vertex area CN.

According to an embodiment, the air provided through the expansion openings OP-E may diffuse to an outside and may push the inner surface of the pad PD. At this time, the air provided through the expansion openings OP-E may diffuse around the sides SD of the core member CR. Accordingly, the outer surface of the pad PD may be generally expanded.

According to an embodiment, the expansion openings OP-E may be formed not only in the vertex area CN of the core member CR but also in each of the sides SD. In such an embodiment, the air provided through the expansion openings OP-E may push not only the inner surface of the pad PD in the vertex area CN but also the inner surface of the pad PD in the sides SD, and thus, the pad PD may be more efficiently expanded. According to an embodiment, the expansion openings OP-E formed adjacent to the sides SD may also be fluidly connected to the air injection opening OP-I.

The pad PD may have different shapes according to whether or not an air supply operation is performed. The pad PD (e.g., the pad edge portion PD-E), according to an embodiment, may have a first outer surface S1 and/or a second outer surface S2. For example, the pad PD may have the first outer surface S1, which is relatively unexpanded by the air provided along the air path AP, and may have the second outer surface S2, which is relatively expanded by the air provided along the air path AP. For reference, an appearance in which an outer surface shape of the pad PD is expanded in FIG. 7 is expressed by dotted arrows.

According to an embodiment, the expansion opening OP-E may push a portion of the pad PD (e.g., the pad edge portion PD-E), which is not covered by the body BD. For example, the pad PD may be expanded by air in an area at where expansion is not limited by the body BD. For example, an outer surface shape of the pad base portion PD-B may not be substantially changed, and an outer surface shape of the pad edge portion PD-E may be changed.

According to an embodiment, a shape of the expanded pad PD may be determined according to an amount of air injected and a shape prepared in advance before the expansion of the pad PD. For example, whether or not the shape of the pad PD is suitably expanded may be determined by comprehensively assessing a pressure inside the pad PD for determining the amount of air injected and a shape observable from an outside.

According to an embodiment, the pad PD may be a structure having a curve portion (e.g., a predetermined curve portion) for molding the display panel DP. According to an embodiment, the pad PD may have a shape that may be adjusted through air injection. Accordingly, the curve portion of the display panel DP may be closely controlled.

In addition, according to an embodiment, the pad PD may have an outer surface shape expanded by air and, thus, may have a clear (e.g., smooth) curve shape in edge areas (e.g., around a vertex) and may stably support the display panel DP when the display panel DP is disposed under the pad PD.

Accordingly, the display panel DP may be generally in closely contact with the outer surface of the pad PD including the vertices. Accordingly, a risk that the display panel DP and the pad PD are not in close contact with each other (e.g., a risk in which an air layer is present between the display panel DP and the pad PD, a buckling phenomenon, or the like) may be substantially reduced.

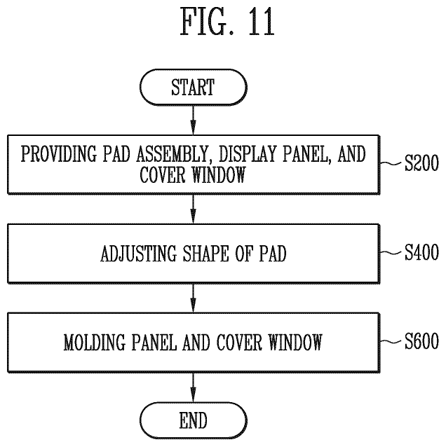

With reference to FIGS. 11 to 14, a method of manufacturing a display device DD according to an embodiment by using a manufacturing apparatus for a display device DD according to an embodiment is described. For convenience of description, content that may overlap or is substantially similar to the content described above is briefly described or is omitted.

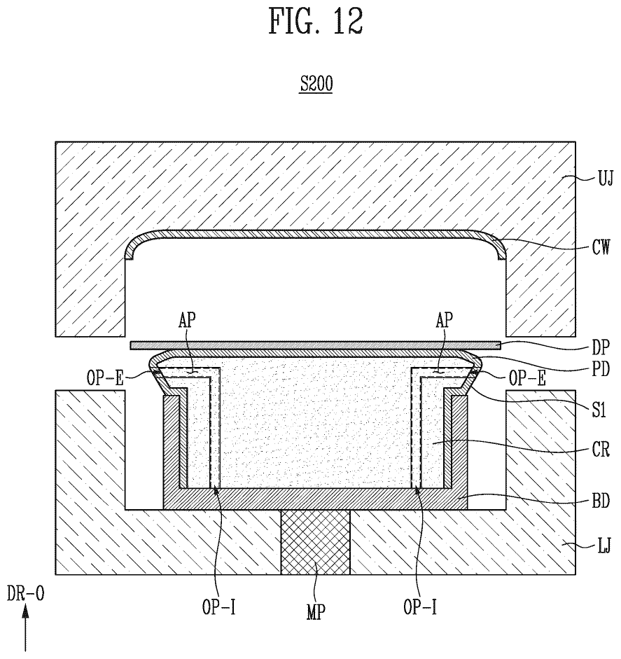

FIG. 11 is a schematic flowchart describing steps of a method of manufacturing a display device according to an embodiment. FIGS. 12 to 14 are schematic drawings illustrating steps of a method of manufacturing a display device DD according to an embodiment. For convenience of description, the adhesive layer ADS is not shown in FIGS. 12 to 14, but the adhesive layer ADS may be interposed between the display panel DP and the cover window CW among the process steps. For example, the adhesive layer ADS may be disposed on the display panel DP and may also be disposed under the cover window CW.

Referring to FIG. 11, a method of manufacturing a display device DD according to an embodiment may include providing a pad assembly, a display panel, and a cover window (S200), adjusting a shape of a pad (S400), and molding the display panel and the cover window (S600).

Referring to FIGS. 11 and 12, in providing the pad assembly, the display panel, and the cover window (S200), the display panel DP and the cover window CW may be provided around a manufacturing apparatus for the display device DD.

According to an embodiment, the manufacturing apparatus for the display device DD may include the pad assembly PAS and may further include a moving member MP, a first jig LJ, and a second jig UJ. In addition, the manufacturing apparatus for the display device DD may further include an external air injection member (e.g., a pump or the like) configured to inject air through the air injection opening OP-I.

The moving member MP may be configured to move the pad assembly PAS in a vertical direction. The moving member MP may move the pad assembly PAS in an operation direction DR-O. The moving member MP may move the pad assembly PAS in a direction from the first jig LJ toward the second jig UJ. The moving member MP may be a support member and may support a lower portion of the pad assembly PAS. At least a portion of the moving member MP may be disposed in an opening portion passing through at least a portion of the first jig LJ. The moving member MP may be implemented by an actuator, such as a servo motor or a cylinder, but the present disclosure is not limited thereto.

The first jig LJ may be a lower jig. The first jig LJ may support a lower outer shape of the manufacturing apparatus for the display device DD and may have an upper surface to contact a portion of the second jig UJ. The first jig LJ may form a space (e.g., a first space), which may receive (or accommodate) the pad assembly PAS and the display panel DP. A portion of the pad assembly PAS may be provided (e.g., disposed or arranged) in the first jig LJ.

The second jig UJ may be an upper jig. The second jig UJ may support an upper outer shape of the manufacturing apparatus for the display device DD and may have a lower surface to contact a portion of the first jig LJ. The second jig UJ may form a space (e.g., a second space), which may receive (or accommodate) the cover window CW. According to an embodiment, as a process step is performed, at least a portion of the pad assembly PAS may be disposed in the space formed by the second jig UJ.

The first jig LJ and the second jig UJ may face each other. The second jig UJ may have a curved surface on which the cover window CW may be disposed. For example, an inner surface of the second jig UJ may have a curved shape corresponding to a shape of the cover window CW.

In the step S200, the display panel DP may be provided, and the display panel DP may be disposed on an upper surface of the pad PD having the first outer surface S1. In the step S200, the pad PD may have an unexpanded shape.

In the step S200, the cover window CW may be disposed and supported on an inner surface of the second jig UJ. The cover window CW may be disposed to face an upper surface of the display panel DP. According to an embodiment, in the step S200, the first jig LJ and the second jig UJ may be provided to be spaced apart from each other.

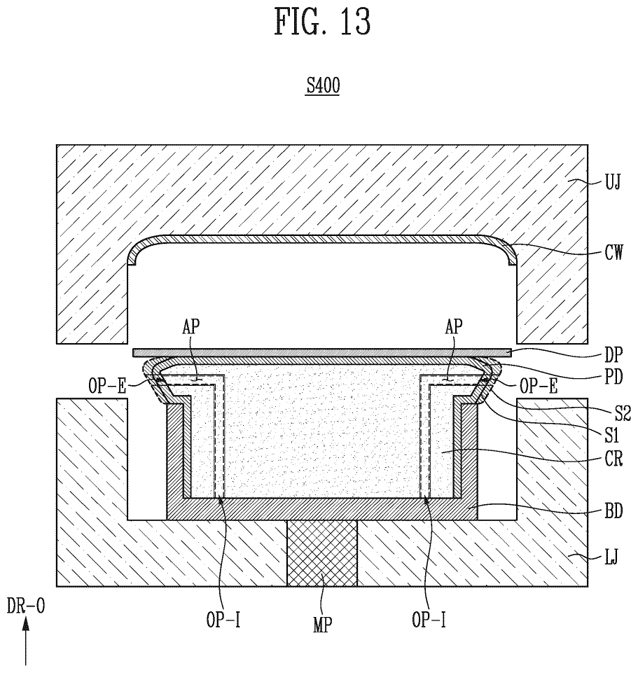

Referring to FIGS. 11 and 13, in adjusting a shape of the pad (S400), the outer surface of the pad PD may be expanded.

In the step S400, the air supplied through the air injection opening OP-I may move along the air path AP and may push the inner surface of the pad PD through the expansion opening OP-E. Accordingly, the pad PD may have the second outer surface S2, which is expanded compared to the first outer surface S1. At this time, because a portion of the pad PD is disposed in the body BD, the expansion of the pad PD disposed in the body BD may be limited, and only a portion of the pad PD that is not disposed in the body BD may be expanded.

In the step S400, the outer surface shape of the pad PD may be adjusted to have a shape suitable for molding the display panel DP. For example, the pad PD may not be excessively bent, and the pad PD may not excessively face a lower portion.

In the step S400, it may be determined whether or not the outer surface of the pad PD is expanded by a suitable range. For example, the outer surface shape of the pad PD may be observed to determine whether or not the pad PD has a suitable (e.g., predetermined) shape. In addition, an internal pressure of the pad PD may be measured to determine whether or not the pad PD is expanded by an intended range. Accordingly, air may be injected through the air path AP until the pad PD has a suitable shape.

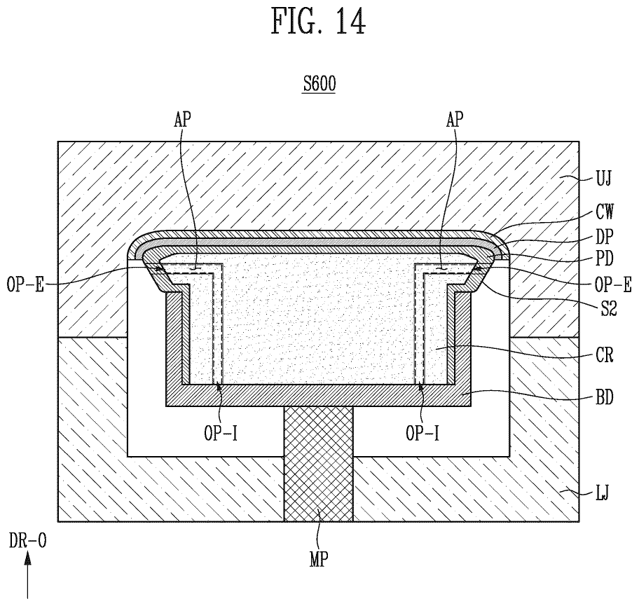

Referring to FIGS. 11 and 14, in forming the display panel and the cover window (S600), the display panel DP and the cover window CW may be molded to correspond to the shape of the pad PD and may be coupled with each other.

In the step S600, because the adhesive layer ADS is interposed between the display panel DP and the cover window CW, the display panel DP and the cover window CW may be coupled with each other.

In the step S600, the pad assembly PAS may be moved in the operation direction DR-O by the moving member MP, and the second jig UJ may be moved downwardly.

In the step S600, the first jig LJ and the second jig UJ may be in contact with each other, and a movement range of the cover window CW and the display panel DP may be limited. Accordingly, the cover window CW and the display panel DP may be coupled in an appropriate operation range.

In the step S600, an upper surface of the display panel DP may push a lower surface of the display panel DP, and the second jig UJ may push an upper surface of the cover window CW. Accordingly, the display panel DP and the cover window CW may be molded similarly to a curved surface shape of the pad PD and may be coupled with each other.

As described above, before a substantial molding process for the display panel DP is performed, the shape of the pad PD may be adjusted, and thus, a molding and attachment process between the display panel DP and the cover window CW may be closely performed.

Thereafter, according to an embodiment, the first jig LJ and the second jig UJ may be spaced apart (e.g., moved apart) from each other, and the display device DD including the display panel DP and the cover window CW may be provided.

Hereinafter, an electronic device 1000 including a display device DD according to an embodiment is described.

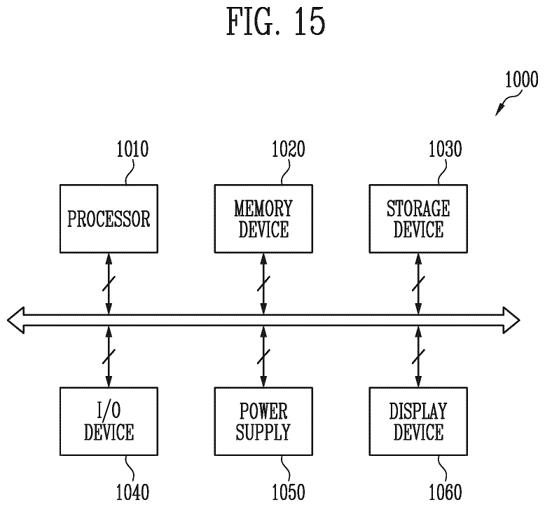

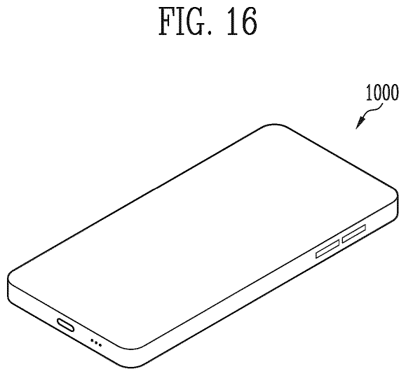

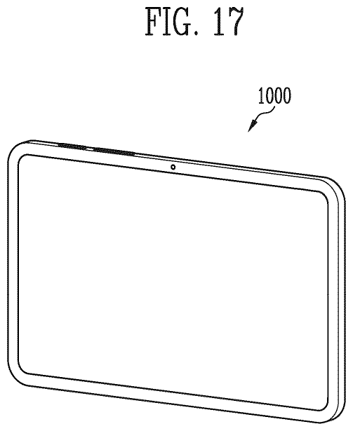

FIG. 15 is a schematic block diagram illustrating an electronic device including a display device according to an embodiment. FIG. 16 is a schematic diagram illustrating an example in which the electronic device shown in FIG. 15 is implemented as a smartphone. FIG. 17 is a schematic diagram illustrating an example in which the electronic device shown in FIG. 15 is implemented as a tablet PC.

Referring to FIGS. 15 to 17, the electronic device 1000 may include a processor 1010, a memory device 1020, a storage device 1030, an input/output device 1040, a power supply 1050, and a display device 1060. The display device 1060 may be the display device DD shown in FIG. 1. In addition, the electronic device 1000 may further include several ports configured to communicate with a video card, a sound card, a memory card, a USB device, or the like, or to communicate with other systems. In an embodiment, as shown in FIG. 16, the electronic device 1000 may be implemented as a smart phone. In another embodiment, as shown in FIG. 17, the electronic device 1000 may be implemented as a tablet PC. However, the electronic device 1000 is not limited thereto. For example, the electronic device 1000 may be implemented as a mobile phone, a video phone, a smart pad, a smart watch, a vehicle navigation device, a computer monitor, a notebook computer, a head mounted display device, or the like.

The processor 1010 may perform specific calculations or tasks. According to an embodiment, the processor 1010 may be a microprocessor, a central processing unit, an application processor, or the like. The processor 1010 may be connected to other components through an address bus, a control bus, a data bus, or the like. According to an embodiment, the processor 1010 may also be connected to an expansion bus, such as a peripheral component interconnect (PCI) bus. According to an embodiment, the processor 1010 may provide input image data to the display device 1060, and thus, the display device 1060 may display an image based on the input image data provided from the processor 1010.

The memory device 1020 may store data to perform an operation of the electronic device 1000. The memory device 1020 may act as working memory and/or buffer memory of the processor 1010. For example, the memory device 1020 may include one or more volatile memory devices, such as a dynamic random access memory (DRAM) device, a static random access memory (SRAM) device, and a mobile DRAM device.

The storage device 1030 may receive a control signal or data from the processor 1010 and may store the data. The storage device 1030 may include one or more nonvolatile storage devices, which may maintain the data even when the electronic device 1000 is turned off. In some embodiments, the storage device 1030 may include a solid state drive (SSD), a hard disk drive (HDD), a CD-ROM, or the like.

The input/output device 1040 may include an input device, such as a keyboard, a keypad, a touch pad, a touch screen, and a mouse, and an output device, such as a speaker and a printer. According to an embodiment, the display device 1060 may be included in the input/output device 1040.

The power supply 1050 may supply power to operate the electronic device 1000. For example, the power supply 1050 may be a power management integrated circuit (PMIC). According to an embodiment, the power supply 1050 may supply power to the display device 1060.

The display device 1060 may display an image corresponding to visual information of the electronic device 1000. The display device 1060 may be connected to other components through the buses or other communication links.

As described above, although the present disclosure has been described with reference to embodiments herein, those skilled in the art or those having ordinary skill in the art will understand that the present disclosure may be variously modified and changed without departing from the spirit and technical area of the present disclosure described in the appended claims.

Therefore, the technical scope of the present disclosure should not be limited to the contents described in the detailed description of the specification but should be defined by the claims and their equivalents.

What is claimed is:

1. A manufacturing apparatus for a display device, the manufacturing apparatus comprising:
a pad assembly comprising a body, a core member, and a pad coupled together and configured to move in a vertical direction; and
a jig configured to accommodate at least a portion of the pad assembly,
wherein at least a portion of the core member is in a body accommodating area formed by the body, and
the core member has an expansion opening covered by the pad and facing an inner surface of the pad.

2. The manufacturing apparatus of claim 1, wherein the display device comprises a display panel,
the pad assembly forms an area at where the display panel is arranged,
at least a portion of the pad is in the body accommodating area, and
at least another portion of the pad extends around an outer surface of at least a portion of the core member that is not in the body accommodating area.

3. The manufacturing apparatus of claim 2, wherein the body, the core member, and the pad are assembled with each other to form the pad assembly.

4. The manufacturing apparatus of claim 2, further comprising a capping layer between the body and the pad in the body accommodating area,
wherein the body, the core member, and the pad are detachably bonded to each other.

5. The manufacturing apparatus of claim 1, wherein the core member forms a core accommodating area, and
at least a portion of the pad protrudes and closely contacts an inner surface of the core member in the core accommodating area.

6. The manufacturing apparatus of claim 1, wherein the core member has a core base portion and a core edge portion integrally formed with each other,
the core base portion is in the body accommodating area, and the core edge portion is not in the body accommodating area, and
the core base portion has a shape and a size corresponding to the body accommodating area.

7. The manufacturing apparatus of claim 5, wherein the core edge portion is covered by a portion of the pad, and
the expansion opening is formed in at least a portion of the core edge portion.

8. The manufacturing apparatus of claim 7, wherein the core member has an air injection opening and an air path fluidly connecting the air injection opening and the expansion opening.

9. The manufacturing apparatus of claim 8, wherein the air path has portions extending in a plurality of different directions.

10. The manufacturing apparatus of claim 8, wherein the expansion opening comprises a plurality of expansion openings, and
a first group of the plurality of expansion openings are at vertex areas of the core edge portion.

11. The manufacturing apparatus of claim 10, wherein the plurality of expansion openings comprises a first expansion opening, a second expansion opening, and a third expansion opening facing in different directions and at different ones of the vertex areas, and
the first expansion opening, the second expansion opening, and the third expansion opening are fluidly connected to the same air injection opening.

12. The manufacturing apparatus of claim 10, wherein a second group of the plurality of expansion openings are at sides of the core edge portion.

13. The manufacturing apparatus of claim 1, wherein the pad has a pad base portion and a pad edge portion integrally formed with each other,
the pad base portion is between the body and the core member in the body accommodating area, and
the pad edge portion is not in the body accommodating area and is not covered by the body.

14. The manufacturing apparatus of claim 13, wherein air supplied through the expansion opening pushes the inner surface of the pad, and
an outer surface shape of the pad is changed in response to the air pushing the inner surface of the pad.

15. The manufacturing apparatus of claim 1, further comprising a moving member configured to move the pad assembly,
wherein the jig comprises a first jig and a second jig facing the first jig, and
the second jig has an inner surface having a curved shape at where a cover window is to be disposed.

16. A method of manufacturing a display device, the method comprising:
providing a pad assembly comprising a body, a core member, and a pad coupled together, a display panel on the pad assembly, and a cover window facing the display panel;
adjusting a shape of the pad; and
molding the display panel and the cover window after the adjusting the shape of the pad.

17. The method of claim 16, wherein the adjusting the shape of the pad comprises expanding a portion of the pad that is not covered by the body by allowing air provided through an air path formed in the core member to push an inner surface of the pad, and
wherein during the adjusting the shape of the pad, a portion of the pad in a body accommodating area formed by the body is not expanded.

18. The method of claim 16, wherein the adjusting the shape of the pad comprises determining whether or not the pad is expanded to be within a range based on an internal pressure of the pad and an external shape of the pad.

19. The method of claim 16, wherein the molding comprises:
allowing a first jig disposed under the pad assembly and a second jig supporting the cover window to be adjacent to each other; and
molding the display panel to correspond to a shape of the pad.

20. An electronic device comprising:
a processor configured to provide input image data;
a display device configured to display an image based on the input image data, comprising sub-pixel areas, and manufactured by the method of claim 16; and
a power supply configured to supply power to the display device.
